(19) United States
(12) Patent Application Publication
(10) Pub. No.: US 2008/0121269 A1
(43) Pub. Date: May 29, 2008

(54) Photovoltaic micro-concentrator modules

(76) Inventors: Roger E. Welser, Providence, RI (US); Paul M. DeLuca, Providence, RI (US); William T. Roberts, North Attleboro, MA (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 11/895,018

(22) Filed: Aug. 22, 2007

Related U.S. Application Data
(60) Provisional application No. 60/839,535, filed on Aug. 23, 2006.

(51) Int. Cl. H01L 31/052; B32B 37/00; H01L 31/04

(52) U.S. Cl. 136/246; 136/259; 156/60

(57) ABSTRACT

A photovoltaic (PV) device comprises at least one PV lamp that includes at least one solar cell chip that generates an electrical current upon exposure to light, and an epoxy lens that encapsulates the solar cell chip, the epoxy lens concentrating incident light onto the solar cell chip. A method of manufacturing a PV device that includes at least one PV lamp comprises fabricating at least one solar cell chip that generates an electrical current upon exposure to light, and forming an epoxy lens that encapsulates the solar cell chip, the epoxy lens concentrating incident light onto the solar cell chip, to thereby form the PV lamp.

### RELATED APPLICATION

This application claims the benefit of U.S. Provisional Application No. 60/839,535, filed on Aug. 23, 2006, the entire teachings of which are incorporated herein by reference.

### BACKGROUND OF THE INVENTION

Photovoltaic technologies hold great promise as a sustainable, environmentally friendly energy source for the 21st century. While photovoltaics (PV) currently provide a minuscule percentage of the world's energy needs, it is a surprisingly large and rapidly growing industry. The worldwide PV market has been growing at over 30% annually since the late 1990s, and now generates over $4.5 billion (US) per year in revenue.

Despite the notable growth in the PV market, several deficiencies in current technologies limit the rate of adoption of PV in the renewable energy marketplace. First, the efficiency at which solar cells convert sunlight into electricity is limited to just over 30% in the best laboratory devices. The performance of commercially available PV devices (or modules) is lower still, with power conversion efficiencies typically under 15%. Moreover, the high manufacturing costs and availability. of crystalline semiconductor solar cells fundamentally constrain the final cost of PV-generated electricity.

Concentrator systems, which replace expensive semiconductor materials with cheaper plastic lens and/or metal mirrors, have long promised to reduce PV device (or module) costs. Moreover, a basic semiconductor device theory generally dictates that the potential efficiency of a solar cell can increase with concentration due to an enhancement in the open circuit voltage. Despite the potential for PV concentrator systems to lower cost and improve performance, the simplicity of one-sun flat-plate technology has overwhelmingly won out in the marketplace. Over the past few years, alternative micro-concentrator designs have been suggested that replicate the low profile of a traditional flat-plate module. These previous micro-concentrator designs, however, rely on complex optical elements and module assembly, and have not proven conducive to low-cost manufacturing.

Therefore, there is a need for developing new PV devices that can address one or more of the aforementioned problems associated with conventional PV devices.

### SUMMARY OF THE INVENTION

The present invention generally relates to a PV device employing at least one PV lamp and to a method of manufacturing such a PV device.

In one embodiment, the invention is directed to a PV device that comprises at least one PV lamp. The PV lamp includes at least one solar cell chip, commonly one solar cell chip, that generates an electrical current upon exposure to light, and an epoxy lens that encapsulates the solar cell chip. The epoxy lens concentrates incident light onto the solar cell chip.

In another embodiment, the invention is directed to a method of manufacturing a PV device that includes at least one PV lamp. The method comprises fabricating at least one solar cell chip, commonly one solar cell chip, that generates an electrical current upon exposure to light, and forming an epoxy lens that encapsulates the solar cell chip to thereby form the PV lamp. The epoxy lens concentrates incident light onto the solar cell chip.

The invention can lower the costs of PV device fabrication. In an embodiment of a solar cell chip inserted into an epoxy dome package to form a PV lamp, similar to that used in LEDs, the epoxy dome package can be fabricated by employing standard LED fabrication technologies known in the art, and, thus, the fabrication cost of a PV device of the invention can be relatively low. Also, in an embodiment where a plurality of micro-concentrator cells, each of which includes a plurality of the PV lamps, are inserted between two panes of material, similar to an insulated window, well-established manufacturing capabilities from the insulated window glass industry can be utilized, resulting in cost-effective fabrication of PV devices.

In addition, in an embodiment where a solar cell chip is embedded in an epoxy lens with a higher index of refraction than air, reductions in semiconductor material (e.g., an about 50% reduction in semiconductor material) to be employed for the solar cell chip can be achieved with a minimal loss in the field of view.

In addition to cost-effective manufacturing advantages of the invention, efficiency and power density of the PV devices of the invention can be increased both by the selection of higher performance solar cells and from the higher open circuit voltage induced by concentration. In particular, in an embodiment of a relatively small solar cell chips, each no larger than one half the size of a standard LED lamp, a low profile similar to conventional flat-plate modules can be obtained, because the module thickness is generally directly related to the dimensions of a PV lamp. Moreover, the heat load can be widely distributed among the plurality of small PV lamps, thus avoiding the need for active cooling that complicates most conventional concentrator system designs.

The PV devices of the invention can be applicable to either relatively low-concentration stationary PV modules or relatively high-concentration systems that require tracking.

### BRIEF DESCRIPTION OF THE DRAWINGS

FIG. 1 is a schematic drawing of one embodiment of a PV lamp that can be employed in a photovoltaic device of the invention.

FIG. 2 is a cross-sectional view of one embodiment of a micro-concentrator cell of a photovoltaic device of the invention.

FIG. 3 is a plan-view schematic of one embodiment of a micro-concentrator cell of a photovoltaic device of the invention, which includes tiled hexagonal PV lamps for close packing.

FIG. 4 shows a cross-sectional schematic illustration of a photovoltaic device of the invention.

### DETAILED DESCRIPTION OF THE INVENTION

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

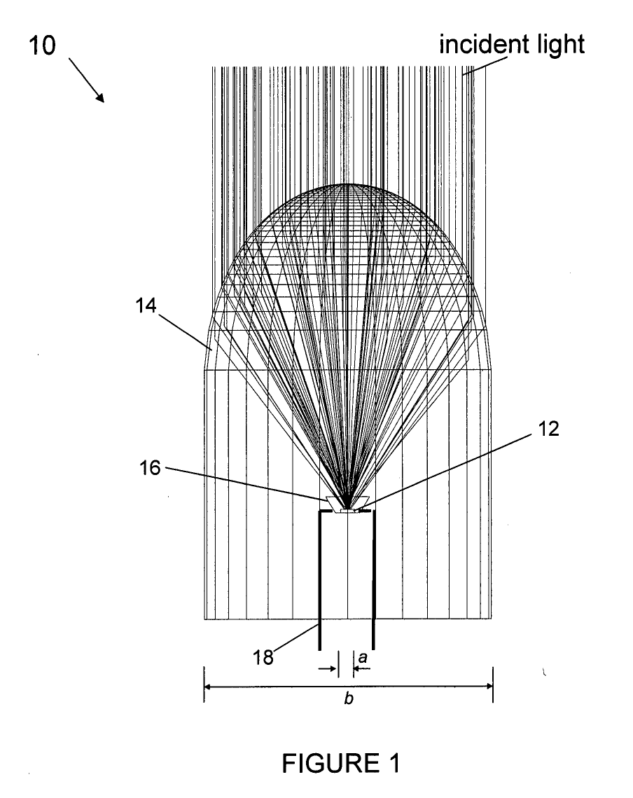

FIG. 1 shows a schematic drawing of one embodiment of PV lamp 10 that includes solar cell chip 12, epoxy lens 14, optional reflector (such as a cup) 16, and optional first electrical contact means 18 (such as lead frame). In FIG. 1, on-axis ray tracing of incident light are also schematically shown.

Solar cell chip 12 typically generates an electrical current upon exposure to light. In one embodiment, solar cell chip 12 has a planar dimension (for example, dimension “a” shown in FIG. 1) of equal to or less than about one half of a largest planar dimension of a base portion of PV lamp 10 (for example, dimension “b” shown in FIG. 1). In a specific embodiment, the base portion of PV lamp 10 has a largest planar dimension in a range of between about 1.8 mm and about 10 mm. In another specific embodiment, the base portion of PV lamp 10 has a largest planar dimension in a range of between about 1 mm and about 5 mm. In yet another specific embodiment, solar cell chip 12 is less than about 100 mm² in area.

The base portion of PV lamp 12 can have any suitable shape. In a specific embodiment, the base portion has a shape chosen from a hexagon, a rectangle and a circle. In a more specific embodiment, the base portion has a hexagon shape.

As shown in FIG. 1, epoxy lens 14 encapsulates solar cell chip 12 and concentrates incident light onto solar cell chip 12. Epoxy lens 14 can have any suitable shape as long as it encapsulates solar cell chip 12 and concentrates incident light onto solar cell chip 12. The shape of the top epoxy surface can act as a lens which can focus incident light onto the solar cell chip. In an embodiment, epoxy lens has a top, dome protrusion, as shown in FIG. 1. In one specific embodiment, epoxy lens 14 has light transmittance of at least about 90%, such as at least about 95%. In another specific embodiment, epoxy lens 14 has light transmittance of at least about 90%, such as at least about 95% over a color range of approximately about 400 nm and about 1400 nm. In yet another specific embodiment, epoxy lens 14 has an index of refraction of about 1.5. There are a wide variety of transparent epoxy resins commercially available. Any suitable epoxy material known in the art, including epoxy materials typically used for LEDs, can be used for epoxy lens 14. Examples of suitable epoxy materials include aromatic and silicon compounds.

Optional reflector 16 peripherally surrounds solar cell chip 12 and reflects at least a portion of incident light onto solar cell chip 12. In a specific embodiment, at least a portion of reflector 16 is encapsulated by epoxy lens 14. In a more specific embodiment, as shown in FIG. 1, reflector 16 is fully encapsulated by epoxy lens 14.

Reflector 16 can have any suitable shape as long as it peripherally surrounds solar cell chip 12 and reflects at least a portion of incident light to solar cell chip 12. In a specific embodiment, reflector 16 is a parabolic reflector, such as a cup.

Optional first electrical contact means 18 electrically connects PV lamp 12 to a circuit board to form a micro-concentrator cell which will be described later. Any suitable electrically conductive material, such as copper, silver, platinum, or lead, or an alloy thereof, can be used for first electrical contact means 18. In a specific embodiment, first electrical contact means 18 is a lead frame typically being used in LED (light emitting diode) industries. In another specific embodiment, at least a portion of first electrical contact means 18, such as a lead frame, is encapsulated by epoxy lens 14. Attachment between solar cell chip 12 and first electrical contact means 18 can be done with any suitable method known in the electrical engineering field. In a specific embodiment, solar cell chip 12 is attached to first electrical contact means 18 with at least one means chosen from a wire bonding, a conducting paste or adhesive, and a flip chip bonding.

Although not shown in FIG. 1, PV lamp 10 can optionally further include a refraction micro-lens between solar cell chip 12 and epoxy lens 14, wherein the refraction micro-lens has a refraction index larger than that of epoxy lens 14, to thereby provide even further concentration of light onto solar cell chip 12.

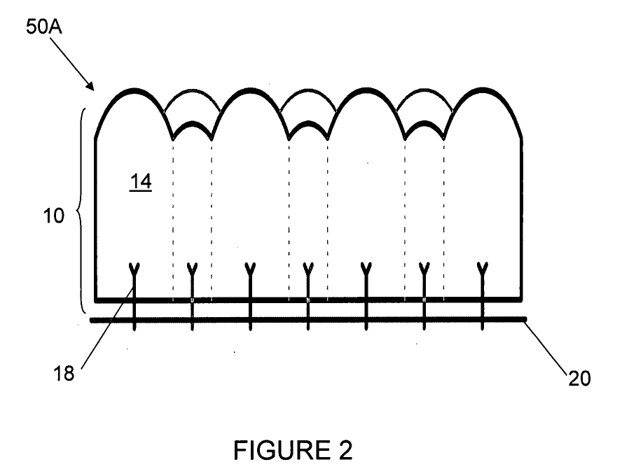

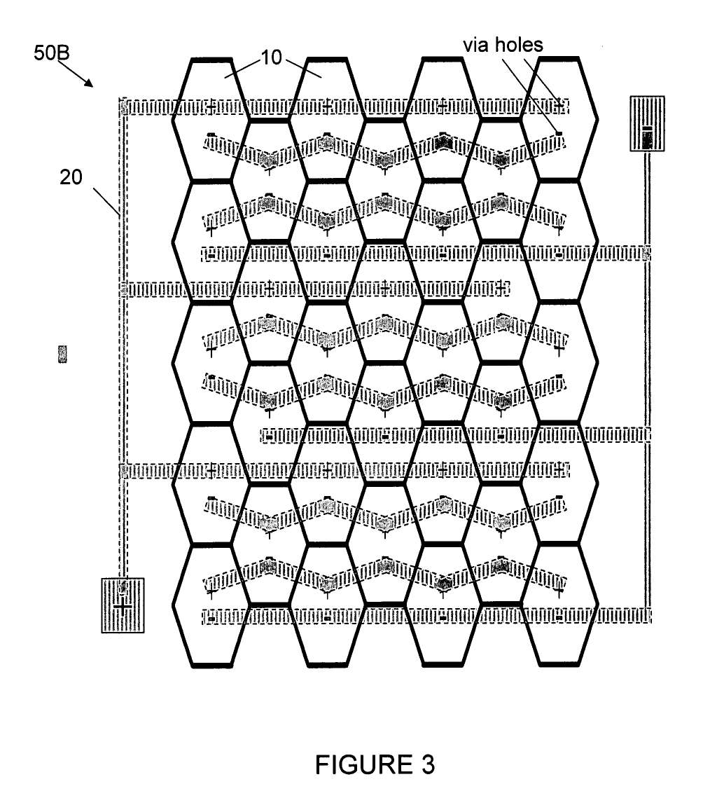

At least one PV lamp 10, such as a plurality of PV lamps 10, can be employed for fabricating a micro-concentrator cell, such as micro-concentrator cell 50 (collectively referring to micro-concentrator cell 50A of FIG. 2 and micro-concentrator cell 50B of FIG. 3) shown in FIG. 2 or 3. In a specific embodiment, at least a portion of PV lamps 10 are arranged in a plane, as shown in FIG. 2.

Micro-concentrator cell 50A of FIG. 2 includes a plurality of PV lamps 10 and circuit board 20, wherein each solar cell chip 12 (see FIG. 1) of PV lamp 10 is in electrical contact with circuit board 20 (e.g., a printed circuit board) through first electrical contact means 18. First electrical contact means 18 can be attached to circuit board 20 with any suitable method, such as a soldering method known in the art. Features of PV lamp 10, including specific features, are as described above.

FIG. 3 shows micro-concentrator cell 50B that includes tiled PV lamps 10 having a hexagonal base for close packing, wherein each PV lamp 10 is electrically connected to circuit board 20 (e.g., printed circuit board (PCB)). The output voltage of micro-concentrator cell 50B can be set by connecting subsets of the lamps together in series, then connecting the subsets in parallel, as shown in FIG. 3. Such electrical connection can be achieved, for example, by inserting PV lamps 10 into appropriately designed circuit board 20 (such as PCB). In a specific embodiment, first electrical contact means 18, such as a lead frame, of PV lamps 10 are inserted into via holes and soldered to circuit board 20. It is noted that, although the illustrative schematics in FIG. 3 depict PV lamps 10 with a hexagonal footprint, a wide range of PV lamp shapes, such as rectangular and circular shapes, can also be employed for close packing in the invention.

Although micro-concentrator cell 50 of FIGS. 2 and 3 employs first electrical contact means 18 to electrically connect solar cell chip 12 with circuit board 20, in some embodiments, solar cell chip 12 is attached directly to circuit board 20.

In some embodiments, although not shown in FIGS. 2 and 3, at least one of micro-concentrator cell 50 further includes a reflector structure on or over circuit board 20. The reflector structure can include one or more metallic layers. Suitable examples of the reflector structure include distributed Bragg reflectors (DBRs), total internal reflectors (TIRs), and omni-directional reflectors (ODRs). The reflectivity of the reflector structure can be tuned by adjusting the thickness, composition, and/or number of layers. Suitable examples of DBRs, TIRs and ODRs can be found in the art, For example, suitable examples of DBRs can be found in Gessmann et al., “Omnidirectional Reflective Contacts for Light-Emitting Diodes,” IEEE Electron Device Letters, vol. 24, pp. 683-685, October 2002, the entire teachings of which are incorporated herein by reference.

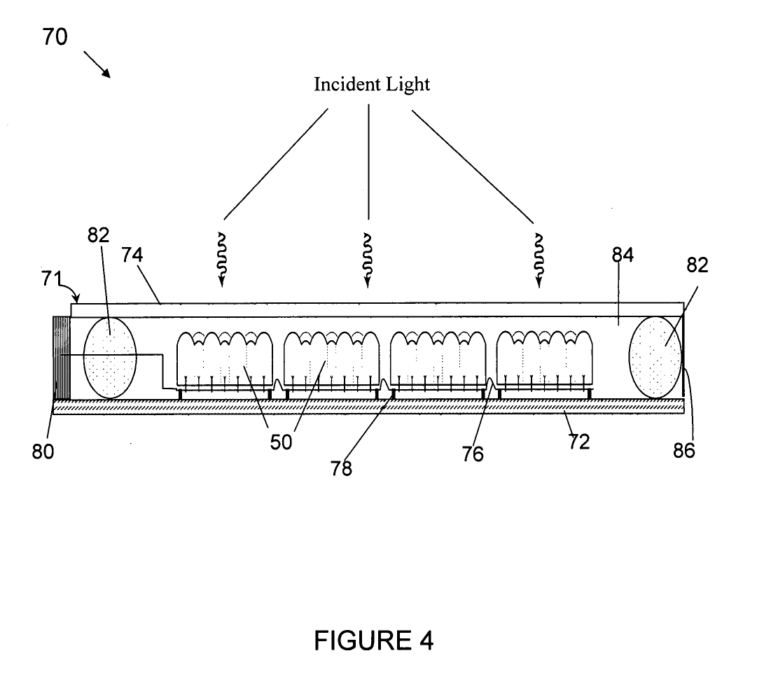

At least one micro-concentrator cell that includes at least one PV lamp 10, such as micro-concentrator cell 50, can be employed for a PV device of the invention, such as PV device 70 shown in FIG. 4. In a specific embodiment, as shown in FIG. 4, at least a portion of micro-concentrator cells 50 are arranged in a plane over a substrate. PV device 70 includes insulating window frame 71 that includes substrate 72, transparent cover 74, and sealants 82 sealing the perimeter of substrate 72 and transparent cover 74. A plurality of micro-concentrator cells 50 are positioned between substrate 72 and transparent cover 74. Micro-concentrator cells 50 are electrically connected with each other through electrical connector 76, and are attached to substrate 72 via connector 78. Space 84 of PV device 70 can be optionally filled with at least one inert gas, such as dinitrogen, helium or argon gas, or a combination thereof. Alternatively, space 84 can be under reduced pressure. An inert gas in space 84 can minimize corrosion of PV device 10. PV device 70 further includes second electrical contact means 80 at a side of PV device 70 through which circuit board 20 of micron-concentrator cell 50 is electrically connected with an external power-output (not shown). PV device 70 further includes side frame 86 at the other side of PV device 70, which can provide mechanical protection at the perimeter of PV device 10.

Substrate 72 is preferably thermally conductive. Suitable examples of substrate 72 include polymers, plastics, glass and metals. In a specific embodiment, substrate 72 is a thermally conductive metal plate, such as aluminum.

Any suitable transparent material, such as glass, known in the insulating window industry can be used for transparent cover 74 in the invention. In a specific embodiment, transparent cover 74 is a Fresnel lens. Fresnel lens can be formed by any suitable method, for example, one known in the art, such as one described in Leutz, et al., “Nonimaging Fresnel Lenses: Design and Performance of Solar Concentrators,” Springer, 2001, the entire teachings of which are incorporated herein by reference.

Any suitable sealing material known in the art, for example, in the insulating window industry, can be used for sealant 82 in the invention. Suitable examples include poly iso-buthylenes, such as those described in Einhaus, et al., “Recent Progress with Apollon Solar's NICE Module Technology,” 20^{th} European Photovoltaic Conference, June 2005, the entire teachings of which are incorporated herein by reference. Ethylene vinyl acetate (EVA) materials can also be used for sealants 82. Alternatively, aluminum materials can also be used for sealants 82.

Features of micro-concentrator cells 50 and PV lamps 10 of PV device 70, including specific features, are each independently as those described above. In a specific embodiment, PV device 70 has a thickness in a range of between about 1 mm and about 5 mm. In another specific embodiment, PV device 70 has a thickness in a range of between about 1 mm and about 5 mm, and the base portion of at least one of PV lamps 10 of micro-concentrator cells 50 has a largest dimension in a range of between about 1 mm and about 5 mm.

PV device 70 can optionally further employ an external reflector, such as a hexagonal CPC (Compound Parabolic Concentrator)-like honeycomb with half dome lens (not shown in FIG. 4). The CPC can be made of fiberglass containing a reflective surface coating and several layers of protective coating. Its reflective surface coating can be aluminum foil, chrome coated metal plate covered with several layers of protective coatings. Alternatively the CPC can be made of a ceramic material provided with a glass-mirror with silver-reflective coating covered with several layers of protective coating. The protective coatings can reduce heat loss and thermal stress at high operating temperatures. In a specific embodiment, PV device 70 employs PV lamps 10 having circular base portions, and an external reflector, such as a hexagonal CPC-like honeycomb with half dome lens. The external reflector can be positioned within the micro-concentrator cells 50, reflecting light on individual lamps 10.

Generally, the number of PV lamps 10 included in PV device 70 to generate a watt of power (assuming a solar input of 1000 W/m²) depends on the lamp dimensions and the overall power conversion efficiency of PV device 70, ranging, for example, from about 4000 lamps with about 1.8 mm average diameter and about 10% efficiency to about 40 lamps with about 10 mm average diameter and about 30% efficiency. Depending upon the desired application, e.g., the desired wattage to be generated, and power conversion efficiency, the number of PV lamps, and their sizes can accordingly be modified.

PV device 70 can be made by any suitable method known in the art. In one embodiment, PV device 70 is manufactured by forming PV lamps 10 utilizing a conventional LED lamp manufacturing technology, assembling micro-concentrator cells 50 utilizing a conventional standard printed circuit board technology, and constructing the final PV device using practices common in the insulated window glass industries. In one specific embodiment, PV device 70 is formed by mounting solar cell chip 12 on first electrical contact means 18, such as a lead frame, prior to soldering it onto circuit board 20. Alternatively, solar-cell chip 12 can be mounted directly to circuit board 20. Epoxy lens 14 is then formed after mounting solar cell chip 12 on circuit board 20. To increase optical collection, an optional reflector structure, such as a reflective honeycomb structure, can then be placed on or over circuit board 20 prior to enclosing the circuit board into insulated window frame 71.

PV lamp 10 can be formed with minimal changes to standard, high-volume, low-cost LED lamps, using an LED lamp fabrication method known in the art, such as one described in Williams, E. W. and Hall, R., “Luminescence and the Light Emitting Diode: The Basic Properties of LEDS and the Luminescence Properties of Materials,” Pergamon Press, 1978, the entire teachings of which are incorporated herein by reference. In one specific embodiment, solar cell chip 12 replaces the LED chip of a conventional LED lamp, and is mounted on first electrical contact means 18, such as a lead frame, which provides electrical contacts and heat sinking. Solar cell chip 12 is then encapsulated with an epoxy material. The epoxy material is molded into a variety of shapes and sizes, such as a round, dome shape.

In one specific embodiment, modification of standard LED lamp fabrication processes is made for light collection suitable for PV lamp 10 of the invention by altering the position of solar cell chip 12 within epoxy lens 14, by altering the design or material type of epoxy lens 14, and/or by altering dimensions of solar cell chip 12. In a more specific embodiment, the depth of solar cell chip 12 from the top of epoxy lens 14 is modified. I In a particular embodiment, the depth of solar cell chip 12 is in a range between about 6 mm and about 6.5 mm from the top of epoxy lens 14. Without being bound to a particular theory, quantitative calculations using a commercial optical simulation package, Zemax, indicate that effective concentration of PV lamp 10 can be increased to nearly 300 times with such depth, as compared with that of PV lamp having solar cell chip 12 at the same depth, from the top of epoxy lens 14, as the conventional LED semiconductor chip (e.g., 5 mm from the top of epoxy lens 14). another, more specific embodiment, the size of solar cell chip 12 of PV lamp 10 is modified. LED lamps typically employ semiconductor chips with dimensions less than 1 mm×1 mm. PV lamps, however, can employ relatively larger solar-cell chips 12, for example, up to half the size of PV lamp 10, depending on the desired concentration and/or heat dissipation. In a particular embodiment, solar cell chip 12 of PV lamp 10 is no larger than one half the size of a standard LED lamp (which is typically in a range of between about 1.8 mm and about 10 mm).

In another specific embodiment, an additional tool available for engineering relatively high light collection in PV lamp 10, fabricated using conventional LED lamp processes, is reflector 16. In a more specific embodiment, parabolic reflector 16 replaces the standard conic profile used in conventional LEDs. The designs of epoxy lens 14 and reflector 16 can also be adjusted to achieve a variety of concentrations, depending on the field-of-view collected by PV lamp 10.

A plurality of PV lamps 10 can be tiled into micro-concentrator cell 50, where the individual lamps are mechanically and electrically connected to each other, employing a suitable standard printed circuit board technology known in the art. Micro-concentrator cells 50 are mechanically attached to substrate 72, and the appropriate electrical cell-to-cell connections are made. In one specific embodiment, the connected micro-concentrator cells are protected from the outside environment using the standard insulated window glass technology known in the art, in which a bead of sealant around the module perimeter is applied and a pane of glass placed on top of the assembly. An inert gas is then be pumped into space 84 through sealant 82 to minimize corrosion.

Solar cell chip 12 can be made by any suitable method, for example, one known in the art, such as U.S. Provisional Application No. 60/926,325, filed Apr. 26, 2007, the entire teachings of which are incorporated herein by reference. Typically, Solar cell chip 12 includes a substrate, a base layer over the substrate and an emitter layer over the base layer. The base layer and the emitter layer forms a p-n diode structure of the solar cell device of the invention. Alternatively, Solar cell chip 12 can include a multi-junction cell having a plurality of subcells. Each of the subcells typically includes a p-n diode structure of a base layer and an emitter layer.

Examples of suitable solar cell substrates include sapphire, silicon, GaAs, GaP, ZnSe and ZnS substrates. The structure may include quantum dots or quantum wells embedded within a wide band gap matrix, typically positioned between the base and emitter layers, i.e., at the p-n junction. One or more of contact metal layers can be further included in the solar cell device of the invention at the bottom of the substrate and over the top emitter layer of the device.

Any suitable semiconductor materials can be used for the p-n diode structures (i.e., base and emitter layers) of solar cell chip 12 of the invention. Suitable examples include silicon, which can be used in various forms, including single crystalline, multicrystalline, and amorphous forms; thin films of, for example, Copper indium diselenide (CIS), cadmium telluride (CdTe); and thin films of Group III-V materials, for example, GaN— (e.g., AlGaN), AlN—, InN—, GaAs—, AlAs—, InAs—, GaP— (e.g., GaInP, AlInGaP), InP—, InGaP— and AlP-based materials, and alloys thereof. In one embodiment, thin films of Group III-V materials are employed for solar cell chip 12 in the invention. In another embodiment, silicon-based thin film materials are employed for solar cell chip 12 in the invention.

Solar cell chip 12, in one embodiment, includes at least one p-n diode structure having an n-type semiconductor layer and a p-type semiconductor layer, each of the n-type and p-type semiconductor layers includes a silicon-based semiconductor material or a Group III-V semiconductor material. In a specific embodiment, solar cell chip 12 further includes a plurality of quantum dots or quantum wells between the n-type and p-type semiconductor layers.

In another embodiment, solar cell chip 12 includes at least one of the following features: a plurality of quantum dots or quantum wells embedded within a wide band gap matrix, an emitter layer with a built-in quasi-electric field, a base later with a built-in quasi-electric field, and at least one photon reflector structure.

Solar cell chip 12, in one specific embodiment, includes an epitaxial p-n junction of a p-n diode structure of the device. The epitaxial p-n junction is formed in a wide band gap semiconductor, wherein a plurality of quantum dots or quantum wells embedded within the wide band gap matrix. The epitaxial p-n junction can be formed via a standard industry method, such as metal organic chemical vapor deposition (MOCVD). Wide band gap material (energy gap>1.6 eV) is desirable to achieve low dark currents that are relatively insensitive to temperature and radiation. Such low dark currents in a p-n diode can provide high operating voltages when the diode is employed as a solar cell with radiation and extreme temperature tolerance. In a preferred embodiment, quantum dots or quantum wells are composed of self-assembled semiconductor material with a lower energy gap than that of the wide band gap matrix, enabling the absorption of photons below the band edge of the wide band gap diode material. The absorption profile of the embedded quantum dots or wells can be tailored by adjusting the composition and dimensions of the individual dots and the number of quantum dot or well layers contained within the p-n junction. The dimensions of the junction depletion region can be adjusted by both the magnitude of the n- and p-type doping adjacent to the junction and by adding un-doped (or intrinsic) material between the n- and p-type layers. The quantum dots or quantum wells embedded within the wide band gap matrix can enhance the current generated by the absorption of photons within the wide band gap p-n junction. Also, such quantum dots or quantum wells can be used to harness photons with energies below the band gap in a two-step process that pumps electrons from the valence band to the conduction band via an intermediate band (see, for example, U.S. Pat. No. 6,444,897, the entire teachings of which are incorporated herein by reference.)

Solar cell chip 12, in another specific embodiment, includes an emitter layer with a built-in quasi-electric field and/or a base layer with a built-in quasi-electric field. Such built-in quasi-electric fields can be generated by grading either the composition of the wide band gap material or the doping level of the wide band gap material, or both. The built-in quasi-electric fields can accelerate photon-generated minority carriers into the depletion region of the p-n junction. Also, when quantum dots (or quantum wells) are embedded within a wide band gap matrix, the built-in quasi-electric fields can minimize or reduce unwanted capturing of carriers in the quantum dots (or quantum wells). Also, the built-in quasi-electric fields can increase the effective diffusion length of minority carriers within the n- and p-type wide band gap material (see, for example, Sassi, “Theoretical Analysis of Solar Cells Based on Graded Band-Gap Structures,” Journal of Applied Physics, vol. 54, pp. 5421-5427, September 1983, the entire teachings of which are incorporated herein by reference). Such enhancement in the diffusion length is particularly beneficial when a wide band gap material, which is lattice mismatched to the substrate, is used either to optimize absorption profiles or lower manufacturing costs.

Solar cell chip 12, in yet another specific embodiment, includes at least one photon reflector structure. When an absorbing substrate is used and photons are incident upon the top of the epitaxial layer structure, the photon reflector structure, such as distributed Bragg reflectors (DBRs), can be positioned between the substrate and the active device layers. Alternatively, the photon reflector structure can be positioned at a back side of the substrate when the photons are incident upon the top of the device. Alternatively, the photon reflector structure can be positioned at the top of the substrate when the photons are incident upon the bottom of the device structure. When the photon reflector structure is positioned at the back and top of the substrate, the photon reflector structure can be added to a metal contact at the bottom and top of the device, respectively. The photon reflector structure can increase the optical path length of incident photons within the active layers of the solar cell device of the invention.

Solar cell chip 12, in yet another specific embodiment, includes a multi-junction solar cell that includes a plurality of subcells, each of which includes a p-n diode structure. In one more specific embodiment, at least one of the subcells includes at least one of the following elements: i) a plurality of quantum dots or wells embedded within a wide band gap matrix, ii) an emitter layer with a built-in quasi-electric field, and iii) a base layer with a built-in quasi-electric field. At least one photon reflector structure can also be included. Features of the quantum dots or wells embedded within a wide band gap matrix, the emitter layer with a built-in quasi-electric field, the base layer with a built-in quasi-electric field; and the photon reflector structure are as described above.

### EQUIVALENTS

While this invention has been particularly shown and described with references to example embodiments thereof, it will be understood by those skilled in the art that various changes in form and details may be made therein without departing from the scope of the invention encompassed by the appended claims.

What is claimed is:

1. A photovoltaic device, comprising at least one photovoltaic lamp that includes:
a) at least one solar cell chip that generates an electrical current upon exposure to light; and
b) an epoxy lens that encapsulates the solar cell chip, the epoxy lens concentrating incident light onto the solar cell chip.

2. The photovoltaic device of claim 1, wherein the epoxy lens has a top, dome protrusion.

3. The photovoltaic device of claim 1, further including a reflector that peripherally surrounds the solar cell chip and reflects at least a portion of incident light onto the solar cell chip.

4. The photovoltaic device of claim 3, wherein at least a portion of the reflector is encapsulated by the epoxy lens.

5. The photovoltaic device of claim 4, wherein the reflector is a parabolic reflector.

6. The photovoltaic device of claim 1, wherein the solar cell chip has a planar dimension of equal to or less than about one half of the largest planar dimension of a base portion of the photovoltaic lamp.

7. The photovoltaic device of claim 6, wherein the base portion of the photovoltaic lamp has a shape selected from the group consisting of a hexagon, a rectangle and a circle.

8. The photovoltaic device of claim 7, wherein the shape of the base portion is a hexagon.

9. The photovoltaic device of claim 6, wherein the solar cell chip is less than about 100 mm² in area.

10. The photovoltaic device of claim 6, wherein the base portion of the photovoltaic lamp has a largest planar dimension in a range of between about 1.8 mm and about 10 mm.

11. The photovoltaic device of claim 1, wherein at least one of the epoxy lenses has light transmittance of at least about 90%.

12. The photovoltaic device of claim 11, wherein at least one of the epoxy lenses has an index of refraction of about 1.5.

13. The photovoltaic device of claim 12, further includes a refraction micro-lens between the solar cell chip and the epoxy lens, the refraction micro-lens having a refraction index larger than the refraction index of the epoxy lens.

14. The photovoltaic device of claim 1, further including a circuit board with which the solar cell chip is in electrical connection, thereby forming a micro-concentrator cell.

15. The photovoltaic device of claim 14, further includes a first electrical contact means that electrically connects the solar cell chip to the circuit board, and wherein at least a portion of the electrical contact means is encapsulated by the epoxy lens.

16. The photovoltaic device of claim 15, wherein the first electrical contact means is a lead frame.

17. The photovoltaic device of claim 14, wherein the device includes a plurality of the photovoltaic lamps, and wherein each solar cell chip of the photovoltaic lamps is in electrical connection with the circuit board of the micro-concentrator cell.

18. The photovoltaic device of claim 17, wherein at least a portion of the photovoltaic lamps are arranged in a plane.

19. The photovoltaic device of claim 18, further including a reflector structure on or over the circuit board.

20. The photovoltaic device of claim 18, wherein each of the solar cell chips includes at least one p-n diode structure having an n-type semiconductor layer and a p-type semiconductor layer, each of the n-type and p-type semiconductor layers includes a silicon-based semiconductor material or a Group III-V semiconductor material.

21. The photovoltaic device of claim 20, wherein the solar cell chip further includes a plurality of quantum dots or quantum wells between the n-type and p-type semiconductor layers.

22. The photovoltaic device of claim 18, wherein the device includes a plurality of the micro-concentrator cells.

23. The photovoltaic device of claim 22, wherein at least a portion of the micro-concentrator cells are arranged in a plane over a substrate.

24. The photovoltaic device of claim 23, further including an electrical connector electrically connecting each micro-concentrator cell.

25. The photovoltaic device of claim 24, further including a transparent cover over the micro-concentrator cells.

26. The photovoltaic device of claim 25, further including a second electrical contact means that electrically connects the circuit board with an external power-output.

27. The photovoltaic device of claim 26, wherein the transparent cover is a Fresnel lens.

28. The photovoltaic device of claim 26, wherein the substrate is a thermally conductive metal plate.

29. The photovoltaic device of claim 26, wherein the device has a thickness in a range of between about 1 mm and about 5 mm.

30. The photovoltaic device of claim 29, wherein the base portion of at least one of the photovoltaic lamps has a largest planar dimension in a range of between about 1 mm and about 5 mm.

31. The photovoltaic device of claim 26, further including a sealant around a perimeter between the substrate and the transparent cover.

32. A method of manufacturing a photovoltaic device that includes at least one photovoltaic lamp, comprising the steps of:
a) fabricating at least one solar cell chip that generates an electrical current upon exposure to light; and
b) forming an epoxy lens that encapsulates the solar cell chip, the epoxy lens concentrating incident light onto the solar cell chip, to thereby form the photovoltaic lamp.

33. The method of claim 32, wherein the epoxy lens is formed to have a top, dome protrusion.

34. The method of claim 32, further including disposing the solar cell chip at a reflector that is peripherally surrounding the solar cell chip and reflects at least a portion of incident light to the solar cell chip.

35. The method of claim 34, wherein at least a portion of the reflector is encapsulated by the epoxy lens.

36. The photovoltaic device of claim 35, wherein the reflector is a parabolic reflector.

37. The method of claim 32, further including attaching the photovoltaic lamp to a circuit board to thereby electrically connect the solar cell chip with the circuit board, thereby forming a micro-concentrator cell.

38. The method of claim 37, wherein the solar cell chip is attached directly to the circuit board.

39. The method of claim 37, wherein the solar cell chip is attached to the circuit board via a first electrical contact means, and wherein at least a portion of the electrical contact means is encapsulated by the epoxy lens.

40. The method of claim 39, wherein the first electrical contact means is soldered to the circuit board.

41. The method of claim 39, wherein the solar cell chip is attached to the first electrical contact means with at least one means selected from the group consisting of a wire bonding, a conducting paste or adhesive, and a flip chip bonding.

42. The method of claim 37, further including fabricating more than one said photovoltaic lamp, wherein each of the photovoltaic lamps is attached to the circuit board of the micro-concentrator cell, to thereby electrically connect each solar cell chip to the circuit board.

43. The method of claim 42, wherein at least a portion of the photovoltaic lamps are arranged in a plane.

44. The method of claim 43, further including fabricating a plurality of the micro-concentrator cells.

45. The method of claim 44, wherein at least a portion of the micro-concentrator cells are arranged in a plane over a substrate.

46. The method of claim 45, wherein the micro-concentrator cells are in electrical contact with each other via an electrical connector.

47. The method of claim 46, further including disposing a transparent cover over the array of the micro-concentrator cells.

48. The method of claim 47, further including electrically connecting the circuit board with an external power-output.
